(19) United States
(12) Patent Application Publication
(10) Pub. No.: US 2025/0204073 A1
(43) Pub. Date: Jun. 19, 2025

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventor: HAJIME YAMAGISHI, KANAGAWA (JP)

(21) Appl. No.: 18/848,061

(22) PCT Filed: Feb. 14, 2023
(86) PCT No.: PCT/JP2023/004872

§ 371 Date: Sep. 17, 2024

(30) Foreign Application Priority Data
Mar. 28, 2022 (JP) 2022-051540

(51) Int. Cl. H10F 39/00

(52) U.S. Cl. CPC H10F 39/807; H10F 39/8037; H10F 39/811

(57) ABSTRACT

The present technology achieves size reduction. A photodetection device includes a semiconductor layer including a pixel formation region and a peripheral region arranged outside the pixel formation region, an isolation region provided in the pixel formation region of the semiconductor layer and including a first conductor extending in a thickness direction of the semiconductor layer, and a second conductor provided in the peripheral region of the semiconductor layer, extending in the thickness direction of the semiconductor layer, and formed in the same layer as the first conductor.

### TECHNICAL FIELD

The present technology (technology according to the present disclosure) relates to a photodetection device and an electronic apparatus, and particularly relates to a technology effective when applied to a photodetection device having a photoelectric conversion region partitioned by an isolation region and an electronic apparatus including the photodetection device.

### BACKGROUND ART

A photodetection device such as a solid-state imaging device or a ranging device includes a semiconductor layer having a photoelectric conversion region partitioned by an isolation region. Patent Document 1 discloses, as the isolation region that partitions the photoelectric conversion region, an embedded isolation region in which a conductor (for example, a doped polysilicon film) is embedded in a dug portion of a semiconductor layer via an insulating film. Further disclosed is a technology to apply a negative bias to the conductor in the isolation region to enhance pinning of a side wall of the isolation region.

On the other hand, Patent Document 2 discloses, as the isolation region that partitions the photoelectric conversion region, a light-shielding isolation region in which a light-shielding portion is embedded in a dug portion of a semiconductor layer via an insulating film. Further disclosed is a technology using the light-shielding portion as a routing wiring on a side of the semiconductor layer adjacent to a light incident surface.

### CITATION LIST

### Patent Document

Patent Document 1: Japanese Patent Application Laid-Open No. 2018-148116
Patent Document 2: Japanese Patent Application Laid-Open No. 2019-114728

### SUMMARY OF THE INVENTION

### Problems to Be Solved by the Invention

Meanwhile, it is also required that the photodetection device be reduced in size to suppress an increase in cost associated with multifunctionality or high functionality.

It is therefore an object of the present technology to achieve size reduction.

### Solutions to Problems

(1) A photodetection device according to an aspect of the present technology includes:
a semiconductor layer including a pixel formation region and a peripheral region arranged outside the pixel formation region;
an isolation region provided in the pixel formation region of the semiconductor layer and including a first conductor extending in a thickness direction of the semiconductor layer; and
a second conductor provided in the peripheral region of the semiconductor layer, extending in the thickness direction of the semiconductor layer, and formed in the same layer as the first conductor.
(2) An electronic apparatus according to another aspect of the present technology includes: a photodetection device according to the above (1); an optical system that forms an image of image light from a subject on an imaging surface of the photodetection device; and a signal processing circuit that performs signal processing on a signal output from the semiconductor device.

### BRIEF DESCRIPTION OF DRAWINGS

FIG. 1 is a schematic plan layout diagram illustrating a configuration example of a solid-state imaging device according to a first embodiment of the present technology.

FIG. 2 is a block diagram illustrating a configuration example of the solid-state imaging device according to the first embodiment of the present technology.

FIG. 3 is an equivalent circuit diagram illustrating a configuration example of a pixel and a pixel circuit of the solid-state imaging device according to the first embodiment of the present technology.

FIG. 4 is a longitudinal cross-sectional view schematically illustrating a longitudinal cross-sectional structure taken along line a1-a1 in FIG. 1.

FIG. 5 is an enlarged longitudinal cross-sectional view of a part of FIG. 4 (right part in the drawing).

FIG. 6 is an enlarged longitudinal cross-sectional view of a part of FIG. 4 (left part in the drawing).

FIG. 7 is a plan view schematically illustrating planar patterns of a bonding pad and a contact electrode in FIG. 6.

FIG. 8 is an enlarged longitudinal cross-sectional view of a part of FIG. 6.

FIG. 9 is an enlarged longitudinal cross-sectional view of a part of FIG. 4 (center part in the drawing).

FIG. 10 is a plan view schematically illustrating a first modification of the first embodiment of the present technology.

FIG. 11 is a plan view schematically illustrating a second modification of the first embodiment of the present technology.

FIG. 12 is a plan view schematically illustrating a third modification of the first embodiment of the present technology.

FIG. 13 is a plan view schematically illustrating a fourth modification of the first embodiment of the present technology.

FIG. 14 is a schematic plan layout diagram illustrating a configuration example of a solid-state imaging device according to a second embodiment of the present technology.

FIG. 15 is a longitudinal cross-sectional view schematically illustrating a longitudinal cross-sectional structure taken along line a14-a14 in FIG. 14.

FIG. 16 is a longitudinal cross-sectional view schematically illustrating a longitudinal cross-sectional structure taken along line b14-b14 in FIG. 14.

FIG. 17 is a schematic plan layout diagram illustrating a configuration example of a solid-state imaging device according to a third embodiment of the present technology.

FIG. 18 is a longitudinal cross-sectional view schematically illustrating a longitudinal cross-sectional structure taken along line a17-a17 in FIG. 17.

FIG. 19 is a diagram illustrating a schematic configuration of an electronic apparatus according to a fourth embodiment of the present technology.

### MODE FOR CARRYING OUT THE INVENTION

Hereinafter, embodiments of the present technology will be described in detail with reference to the drawings.

In the illustration of the drawings referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description.

Furthermore, it goes without saying that dimensional relationships and ratios are partly different between the drawings. Furthermore, the effects described herein are merely examples and are not limited, and other effects may be provided.

Furthermore, the following embodiments illustrate a device and a method for embodying the technical idea of the present technology, and do not specify the configuration as follows. That is, various modifications can be made to the technical idea of the present technology within the technical scope described in the claims.

Furthermore, the definitions of directions such as up and down in the following description are merely defined for convenience of description, and do not limit the technical idea of the present technology. It goes without saying that, for example, when an object is rotated by 90° and observed, the up-and-down direction is converted and read as a left-and-right direction, and when an object is rotated by 180° and observed, the top side is read as the bottom side, and the bottom side is read as the top side.

Furthermore, in the following embodiments, a case will be exemplarily described where a first conductivity type is p-type and a second conductivity type is n-type, but the relationship between the conductivity types may be inversed, that is, the first conductivity type may be n-type and the second conductivity type may be p-type.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a semiconductor layer 21 to be described later will be described as the Z direction.

### First Embodiment

In the first embodiment, an example in which the present technology is applied to a solid-state imaging device called a back-illuminated complementary metal oxide semiconductor (CMOS) image sensor will be described as a photodetection device.

### Overall Configuration of Solid-State Imaging Device

First, an overall configuration of a solid-state imaging device 1A will be described.

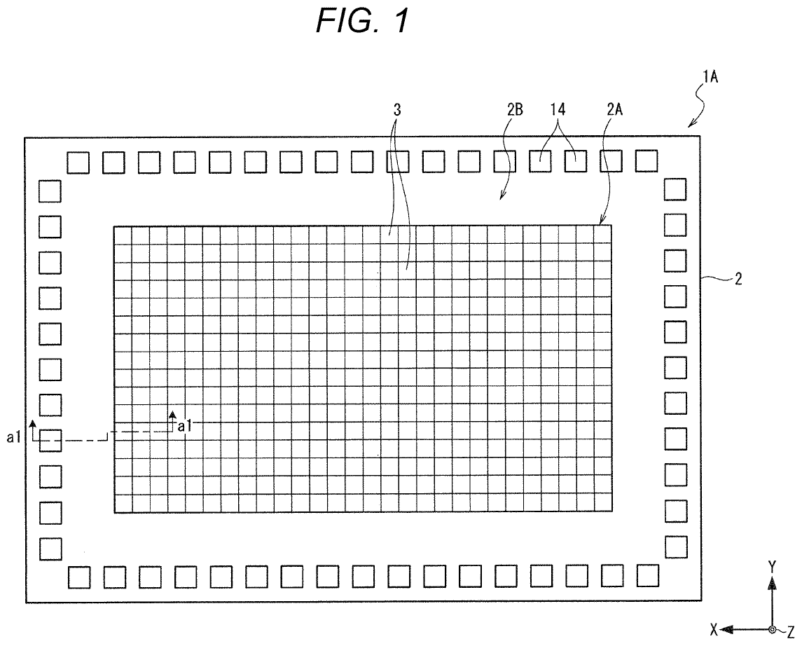

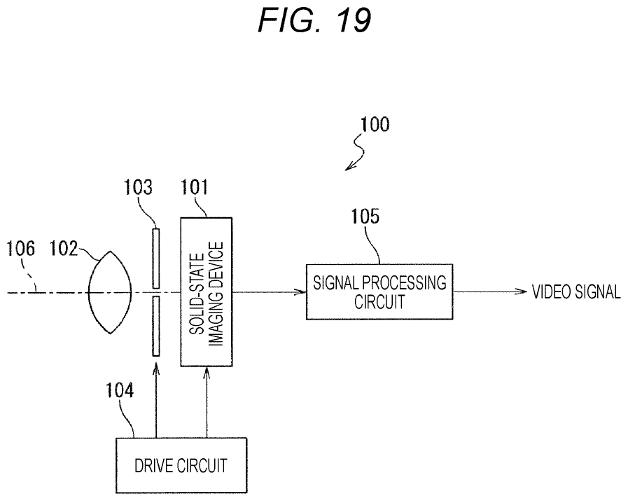

As illustrated in FIG. 1, the solid-state imaging device 1A according to the first embodiment of the present technology mainly includes a semiconductor chip 2 having a rectangular two-dimensional planar shape in plan view. That is, the solid-state imaging device 1A is mounted on the semiconductor chip 2, and the semiconductor chip 2 can be regarded as the solid-state imaging device 1A. As illustrated in FIG. 19, the solid-state imaging device 1A (101) receives image light (incident light 106) from a subject through an optical lens 102, converts an amount of the incident light 106 formed as an image on an imaging surface into an electrical signal for each pixel, and outputs the electrical signal as a pixel signal (image signal).

As illustrated in FIG. 1, the semiconductor chip 2 on which the solid-state imaging device 1A is mounted includes, in a two-dimensional plane including the X direction and the Y direction orthogonal to each other, a rectangular pixel array portion 2A provided in a center portion, and a peripheral portion 2B provided outside and around the pixel array portion 2A. A semiconductor wafer including the semiconductor layer 21 to be described later is diced into small pieces, each serving as a chip formation region, to form the semiconductor chip 2 in a manufacturing process. Therefore, the configuration of the solid-state imaging device 1A to be described below is roughly the same as the configuration before the semiconductor wafer is diced into small pieces. That is, the present technology is applicable to both a semiconductor chip and a semiconductor wafer.

The pixel array portion 2A is, for example, a light receiving surface that receives light condensed by the optical lens (optical system) 102 illustrated in FIG. 19. Then, in the pixel array portion 2A, a plurality of pixels 3 is arranged in a matrix in the two-dimensional plane including the X direction and the Y direction. In other words, the pixels 3 are repeatedly arranged in the X direction and the Y direction orthogonal to each other in the two-dimensional plane.

As illustrated in FIG. 1, a plurality of bonding pads 14 is arranged in the peripheral portion 2B. Each of the plurality of bonding pads 14 is arranged, for example, along a corresponding one of the four sides of the two-dimensional plane of the semiconductor chip 2. Each of the plurality of bonding pads 14 functions as an input/output terminal that electrically connects the semiconductor chip 2 and an external device.

### Logic Circuit

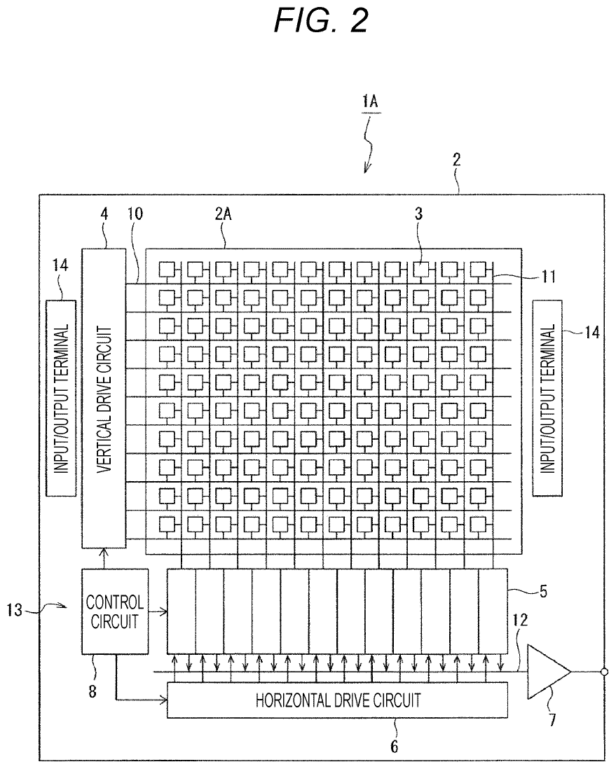

The semiconductor chip 2 includes a logic circuit 13 illustrated in FIG. 2. As illustrated in FIG. 2, the logic circuit 13 includes a vertical drive circuit 4, a column signal processing circuit 5, a horizontal drive circuit 6, an output circuit 7, a control circuit 8, and the like. The logic circuit 13 includes, for example, a complementary MOS (CMOS) circuit including an n-channel conductive metal oxide semiconductor field effect transistor (MOSFET) and a p-channel conductive MOSFET as field effect transistors.

The vertical drive circuit 4 includes a shift register, for example. The vertical drive circuit 4 sequentially selects a desired pixel drive line 10, and supplies a pulse for driving the pixel 3 to the selected pixel drive line 10 to drive each pixel 3 row by row. That is, the vertical drive circuit 4 selectively scans each pixel 3 of the pixel array portion 2A sequentially in a vertical direction row by row, and supplies a pixel signal from each pixel 3 based on a signal charge generated in accordance with the amount of light received by a photoelectric conversion portion (photoelectric conversion element) of the pixel 3 to the column signal processing circuit 5 through a vertical signal line 11.

The column signal processing circuit 5 is arranged, for example, for each column of the pixels 3 and performs signal processing, such as noise removal, on signals output from the pixels 3 of one row, for each pixel column. For example, the column signal processing circuit 5 performs signal processing such as correlated double sampling (CDS) for removing pixel-specific fixed pattern noise, and analog digital (AD) conversion.

The horizontal drive circuit 6 includes a shift register, for example. The horizontal drive circuit 6 sequentially outputs horizontal scanning pulses to the column signal processing circuits 5 to sequentially select each of the column signal processing circuits 5, and causes each of the column signal processing circuits 5 to output a pixel signal subjected to the signal processing to a horizontal signal line 12.

The output circuit 7 performs signal processing on the pixel signal sequentially supplied from each of the column signal processing circuits 5 through the horizontal signal line 12, and outputs the resultant signal. As the signal processing, buffering, black level adjustment, column variation correction, various kinds of digital signal processing, and the like can be used, for example.

The control circuit 8 generates, on the basis of a vertical synchronization signal, a horizontal synchronization signal, and a master clock signal, a clock signal or a control signal in accordance with which the vertical drive circuit 4, the column signal processing circuit 5, the horizontal drive circuit 6, and the like operate. Then, the control circuit 8 then outputs the generated clock signal or control signal to the vertical drive circuit 4, the column signal processing circuits 5, the horizontal drive circuit 6, and the like.

### Circuit Configuration of Pixel

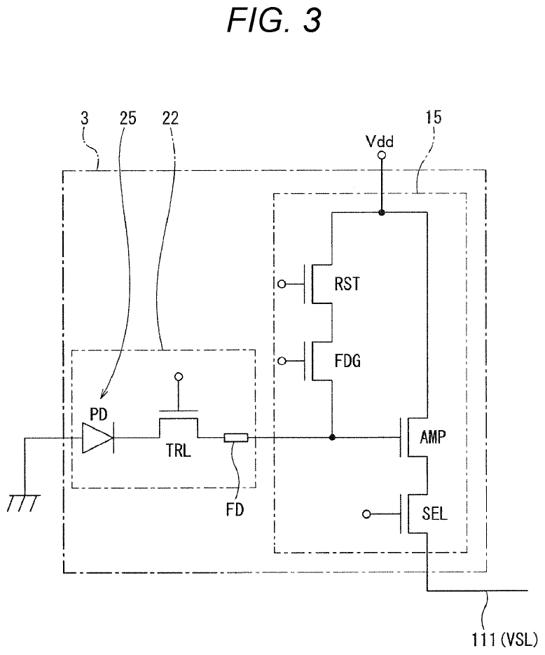

As illustrated in FIG. 3, each of the plurality of pixels 3 includes a photoelectric conversion region 22 and a pixel circuit (readout circuit) 15. The photoelectric conversion region 22 includes a photoelectric conversion portion 25, a transfer transistor TR, and a charge holding region (floating diffusion) FD. The pixel circuit 15 is electrically connected to the charge holding region FD of the photoelectric conversion region 22. The first embodiment has, as an example, a circuit configuration where one pixel circuit 15 is exclusively used by one pixel 3, but the circuit configuration is not limited thereto, and a circuit configuration where one pixel circuit 15 is shared by a plurality of pixels 3 may be employed. For example, a circuit configuration where one pixel circuit 15 is shared by four pixels 3 (one pixel block) arranged in a two-by-two layout, that is, two pixels 3 are arranged in the X direction and two pixels 3 are arranged in the Y direction, may be employed.

The photoelectric conversion portion 25 illustrated in FIG. 3 includes, for example, a pn junction photodiode (PD), and generates a signal charge in accordance with the amount of received light. The photoelectric conversion portion 25 has a cathode side electrically connected to a source region of the transfer transistor TR, and an anode side electrically connected to a reference potential line (for example, ground).

The transfer transistor TR illustrated in FIG. 3 transfers the signal charge generated by photoelectric conversion in the photoelectric conversion portion 25 to the charge holding region FD. The transfer transistor TR has the source region electrically connected to the cathode side of the photoelectric conversion portion 25, and a drain region electrically connected to the charge holding region FD. Then, the transfer transistor TR has a gate electrode electrically connected to a transfer transistor drive line among the pixel drive lines 10 (see FIG. 2).

The charge holding region FD illustrated in FIG. 3 temporarily holds (accumulates) the signal charge transferred from the photoelectric conversion portion 25 via the transfer transistor TR.

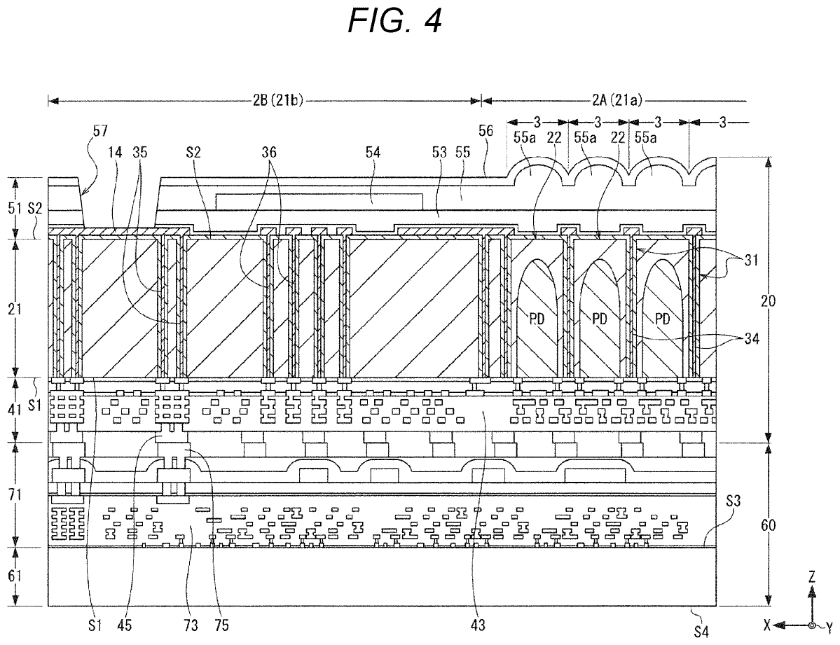

The photoelectric conversion region 22 including the photoelectric conversion portion 25, the transfer transistor TR, and the charge holding region FD is provided in the semiconductor layer 21 (see FIG. 4) to be described later. Furthermore, for example, pixel transistors (AMP, SEL, RST, FDG) included in the pixel circuit 15 are also provided in the semiconductor layer 21, but are not limited to such a configuration.

The pixel circuit 15 illustrated in FIG. 3 reads the signal charge held in the charge holding region FD, converts the read signal charge into a pixel signal, and outputs the pixel signal. In other words, the pixel circuit 15 converts the signal charge generated by photoelectrical conversion in the photoelectric conversion element PD into a pixel signal based on the signal charge and outputs the pixel signal. The pixel circuit 15 includes, but not limited to, an amplification transistor AMP, a selection transistor SEL, a reset transistor RST, and a switching transistor FDG as the pixel transistors, for example. Such pixel transistors (AMP, SEL, RST, FDG) and the above-described transfer transistor TR are each include, for example, a MOSFET as a field effect transistor. Furthermore, these transistors may be MISFETs.

Among the pixel transistors included in the pixel circuit 15, the selection transistor SEL, the reset transistor RST, and the switching transistor FDG each function as a switching element, and the amplification transistor AMP functions as an amplification element.

Note that the selection transistor SEL and the switching transistor FDG may be omitted as necessary.

As illustrated in FIG. 3, the amplification transistor AMP has a source region electrically connected to a drain region of the selection transistor SEL, and a drain region electrically connected to a power supply line Vdd and a drain region of the reset transistor RST. Then, the amplification transistor AMP has a gate electrode electrically connected to the charge holding region FD and a source region of the switching transistor FDG.

The selection transistor SEL has a source region electrically connected to the vertical signal line 11 (VSL), and the drain region electrically connected to the source region of the amplification transistor AMP. Then, the selection transistor SEL has a gate electrode electrically connected to a selection transistor drive line among the pixel drive lines 10 (see FIG. 2).

The reset transistor RST has a source region electrically connected to a drain region of the switching transistor FDG, and the drain region electrically connected to the power supply line Vdd and the drain region of the amplification transistor AMP. Then, the reset transistor RST has a gate electrode electrically connected to a reset transistor drive line among the pixel drive lines 10 (see FIG. 2).

The switching transistor FDG has the source region electrically connected to the charge holding region FD and the gate electrode of the amplification transistor AMP, and the drain region electrically connected to the source region of the reset transistor RST. Then, the switching transistor FDG has a gate electrode electrically connected to a switching transistor drive line among the pixel drive lines 10 (see FIG. 2).

Note that, in a case where the selection transistor SEL is omitted, the source region of the amplification transistor AMP is electrically connected to the vertical signal line (VSL) 11. Furthermore, in a case where the switching transistor FDG is omitted, the source region of the reset transistor RST is electrically connected to the gate electrode of the amplification transistor AMP and the charge holding region FD.

When being turned on, the transfer transistor TR transfers the signal charge generated in the photoelectric conversion portion 25 to the charge holding region FD.

When being turned on, the reset transistor RST resets a potential (signal charge) of the charge holding region FD to a potential of the power supply line Vdd. The selection transistor SEL controls the output timing of the pixel signal from the pixel circuit 15.

The amplification transistor AMP generates a signal of a voltage corresponding to the level of the signal charge held in the charge holding region FD as the pixel signal. The amplification transistor AMP functions as a source follower amplifier, and outputs a pixel signal of a voltage corresponding to the level of the signal charge generated in the photoelectric conversion portion 25. When the selection transistor SEL is turned on, the amplification transistor AMP amplifies the potential of the charge holding region FD, and outputs a voltage corresponding to the potential to the column signal processing circuit 5 via the vertical signal line (VSL) 11.

The switching transistor FDG controls charge holding by the charge holding region FD, and adjusts a voltage multiplication factor according to the potential amplified by the amplification transistors AMP.

While the solid-state imaging device 1A according to the first embodiment is in operation, the signal charge generated in the photoelectric conversion portion 25 of the pixel 3 is held (accumulated) in the charge holding region FD via the transfer transistor TR of the pixel 3. Then, the signal charge held in the charge holding region FD is read out by the pixel circuit 15 and applied to the gate electrode of the amplification transistor AMP of the pixel circuit 15. A horizontal selection control signal is supplied from the vertical shift register to the gate electrode of the selection transistor SEL of the pixel circuit 15. Then, setting the selection control signal to a high (H) level brings the selection transistor SEL into conduction to allow a current corresponding to the potential of the charge holding region FD, amplified by the amplification transistor AMP, to flow to the vertical signal line 11. Furthermore, setting a reset control signal to be applied to the gate electrode of the reset transistor RST of the pixel circuit 15 to the high (H) level brings the reset transistor RST into conduction to reset the signal charge accumulated in the charge holding region FD.

### Specific Configuration of Solid-State Imaging Device

Next, a specific configuration of the solid-state imaging device 1A will be described.

As illustrated in FIG. 4, the semiconductor chip 2 includes a first substrate portion 20 and a second substrate portion 60 that are stacked to face each other in the thickness direction (Z direction). The first substrate portion 20 is provided with the pixel array portion 2A, the peripheral portion 2B, the pixel transistors included in each pixel circuit 15, the bonding pads 14, and the like described above. The second substrate portion 60 is provided with the logic circuit 13 and the like described above.

Here, the first substrate portion 20 may be referred to as first semiconductor substrate or photoelectric conversion substrate portion. Furthermore, the second substrate portion 60 may be referred to as second semiconductor substrate or a circuit substrate portion.

### First Substrate Portion

As illustrated in FIG. 4, the first substrate portion 20 includes the semiconductor layer 21 having a first surface S1 and a second surface S2 located on opposite sides in the thickness direction (Z), a multilayer wiring layer 41 provided adjacent to the first surface S1 of the semiconductor layer 21, and an optical layer 51 provided adjacent to the second surface S2 of the semiconductor layer 21.

Here, in the first embodiment, the semiconductor layer 21 corresponds to a specific example of a “semiconductor layer” or a “first semiconductor layer” of the present technology.

### Semiconductor Layer

As illustrated in FIGS. 4, 5, 6, and 9, the semiconductor layer 21 extends two-dimensionally over the pixel array portion 2A and the peripheral portion 2B, and coincides with the pixel array portion 2A and the peripheral portion 2B in plan view. That is, the semiconductor layer 21 includes a pixel formation region 21a included in the pixel array portion 2A and a peripheral region 21b included in the peripheral portion 2B. Although not illustrated in detail, the peripheral region 21b is provided outside and around the pixel formation region 21a, in a manner similar to the peripheral portion 2B provided around the pixel array portion 2A.

As the semiconductor layer 21, a Si substrate, a SiGe substrate, an InGaAs substrate, or the like may be used. In the first embodiment, the semiconductor layer 21 is, but not limited to, a semiconductor substrate that includes, for example, silicon (Si) as a semiconductor material, and is monocrystalline, for example, and of a p-conductive type, for example.

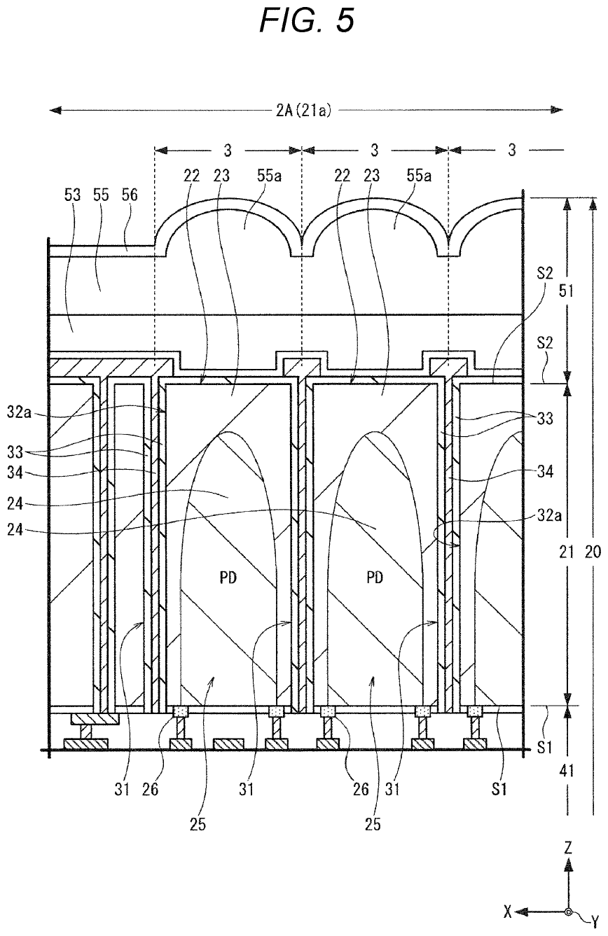

As illustrated in FIG. 5, the pixel formation region 21a of the semiconductor layer 21 is provided with an isolation region 31 extending in the thickness direction (Z direction) of the semiconductor layer 21 and a plurality of the photoelectric conversion regions 22 partitioned by the isolation region 31. The plurality of photoelectric conversion regions 22 is provided on a one-to-one basis for each pixel 3, and is adjacent to each other with the isolation region 31 interposed therebetween in plan view.

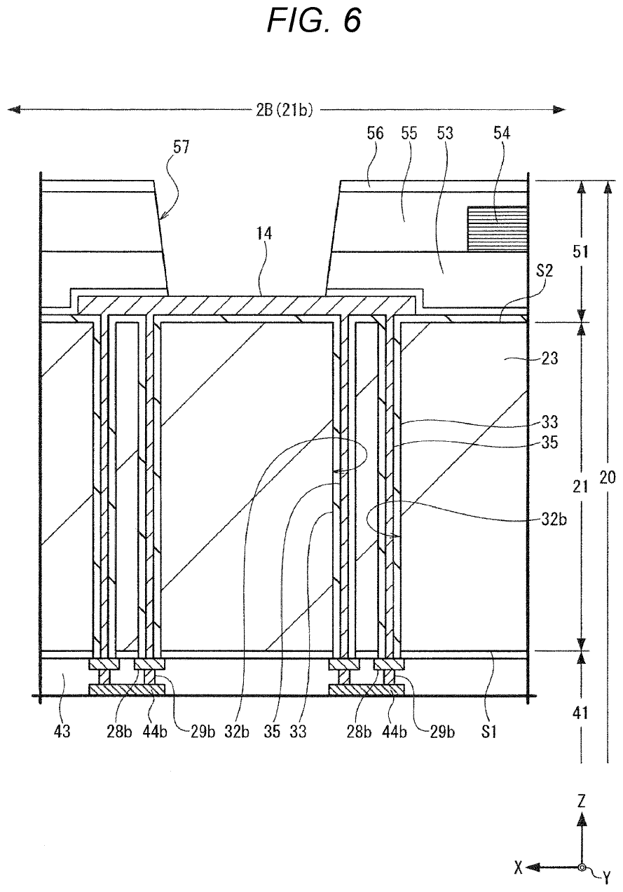

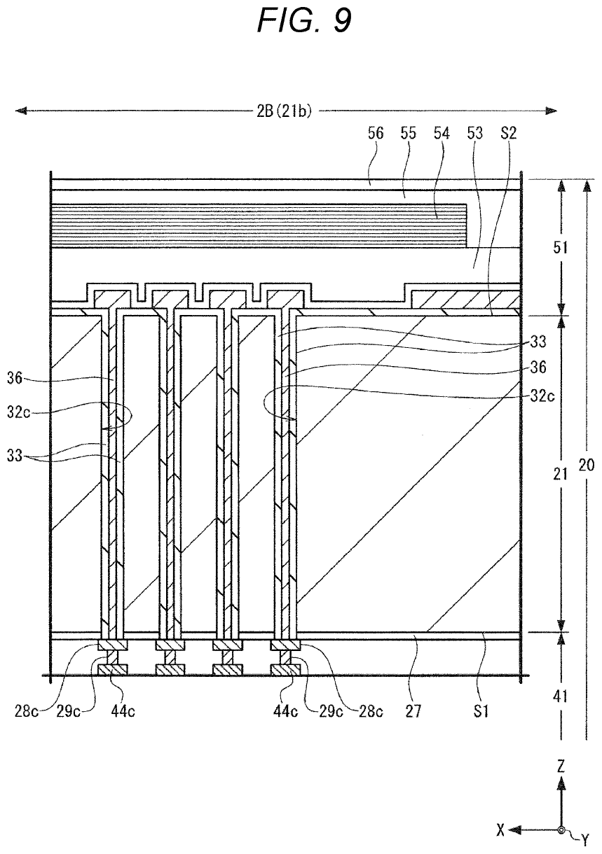

Furthermore, as illustrated in FIGS. 6 and 9, a relay wiring 35 (see FIG. 6) and a back wiring 36 (see FIG. 9) as a “second conductor” of the present technology are provided in the peripheral region 21b of the semiconductor layer 21. That is, the solid-state imaging device 1A of the first embodiment uses the peripheral region 21b of the semiconductor layer 21 as a formation region for the relay wiring 35 and the back wiring 36 as the second conductor.

Here, the first surface S1 of the semiconductor layer 21 may be also referred to as element formation surface or principal surface, and the second surface S2 may be also referred to as light incident surface or back surface. In the solid-state imaging device 1A of the first embodiment, light incident through the second surface (light incident surface, back surface) S2 of the semiconductor layer 21 is photoelectrically converted by the photoelectric conversion region 22 (photoelectric conversion portion 25) provided in the semiconductor layer 21.

Furthermore, the plan view refers to a case where the semiconductor layer 21 is viewed from a direction along the thickness direction (Z direction) of the semiconductor layer 21. Furthermore, the cross-sectional view refers to a case where a cross section along the thickness direction (Z direction) of the semiconductor layer 21 is viewed from a direction (X direction or Y direction) orthogonal to the thickness direction (Z direction) of the semiconductor layer 21. Furthermore, the photoelectric conversion region 22 can also be referred to as photoelectric conversion cell.

### Photoelectric Conversion Region

As illustrated in FIG. 5, each of the plurality of photoelectric conversion regions (photoelectric conversion cells) 22 includes a p-type well region 23 provided in the semiconductor layer 21, an n-type semiconductor region 24 provided in the p-type well region 23, and the photoelectric conversion portion 25 described above.

Furthermore, although not illustrated in FIG. 5, each photoelectric conversion region 22 includes the charge holding region FD and the transfer transistor TR described above. Then, the pixel transistors (AMP, SEL, RST, FDG) included in the pixel circuit 15 described above are provided for each photoelectric conversion region 22 or for a plurality of the photoelectric conversion regions 22. Note that FIG. 5 illustrates a gate electrode 26 of the transfer transistor TR.

As illustrated in FIG. 5, the p-type well region 23 extends from the first surface S1 to the second surface S2 of the semiconductor layer 21, and includes, for example, a p-type semiconductor region.

The photoelectric conversion portion 25 mainly includes the n-type semiconductor region 24, and functions as a pn junction photodiode (PD) formed by a pn junction of the p-type well region 23 and the n-type semiconductor region 24.

### Isolation Region

As illustrated in FIG. 5, the isolation region 31 extends in the thickness direction (Z direction) of the semiconductor layer 21, and electrically and optically isolates the photoelectric conversion regions 22 adjacent to each other in plan view. The isolation region 31 includes a dug portion 32a extending in the thickness direction of the semiconductor layer 21, an insulating film 33 provided along an inner wall (side wall and bottom wall) of the dug portion 32a, and a first conductor 34 provided in the dug portion 32a with the insulating film 33 interposed between the first conductor 34 and the inner wall. The first conductor 34 extends in the thickness direction of the semiconductor layer 21. As illustrated in FIGS. 5, 6, and 9, the insulating film 33 is provided over the second surface S2 of the semiconductor layer 21 and the dug portion 32a, and is provided over the pixel formation region 21a and the peripheral region 21b of the semiconductor layer 21.

That is, the solid-state imaging device 1A of the first embodiment includes the semiconductor layer 21 having the pixel formation region 21a and the peripheral region 21b arranged outside the pixel formation region 21a, and the isolation region 31 provided in the pixel formation region 21a of the semiconductor layer 21 and including the first conductor 34 extending in the thickness direction (Z direction) of the semiconductor layer 21.

The first embodiment has, but not limited to, a configuration where the dug portion 32a extends through the semiconductor layer 21 from the first surface S1 to the second surface S2, and the first conductor 34 is provided in the dug portion 32a extending through the semiconductor layer 21.

The first conductor 34 is electrically isolated from the semiconductor layer 21 by the insulating film 33. Then, although not limited thereto, a first reference potential of, for example, 0 V is applied to the first conductor 34 as a power supply potential. Then, the potential of the first conductor 34 is fixed to the first reference potential during photoelectric conversion in the photoelectric conversion portion 25 or during driving of the pixel transistors (AMP, SEL, RST, FDG) included in the pixel circuit 15.

As the insulating film 33, for example, a silicon oxide (SiO₂) film may be used. As the first conductor 34, for example, an aluminum (Al) film, a tungsten (W) film, a copper (Cu) film, an alloy film containing aluminum or copper as a principal component, or the like may be used.

For example, the first conductor 34 may be formed as follows: forming the dug portion 32a and the insulating film 33 in the semiconductor layer 21; then forming a conductive film on a side, adjacent to the second surface S2, of the semiconductor layer 21 including the inside of the dug portion 32a; then planarizing the surface of the conductive film; and then patterning the planarized conductive film.

### Bonding Pad

As illustrated in FIG. 6, the bonding pad 14 is provided adjacent to the second surface S2 of the peripheral region 21b of the semiconductor layer 21, that is, remote from the multilayer wiring layer 41 of the semiconductor layer 21. Specifically, the bonding pad 14 is provided on the second surface S2 of the peripheral region 21b of the semiconductor layer 21 with the insulating film 33 interposed between the bonding pad 14 and the second surface S2. In FIG. 6, one bonding pad 14 is illustrated as an example, but a plurality of the bonding pads 14 is provided on the second surface S2 of the peripheral region 21b of the semiconductor layer 21 with the insulating film 33 interposed between the bonding pads 14 and the second surface S2.

### Multilayer Wiring Layer

As illustrated in FIG. 4, the multilayer wiring layer 41 is provided adjacent to the first surface S1 of the semiconductor layer 21 that is remote from the light incident surface (second surface S2), and includes a plurality of wiring layers including wiring, the plurality of wiring layers being stacked with an interlayer insulating film 43 interposed between the wiring layers. Wirings of different wiring layers are electrically connected by a contact electrode (via plug). Then, the multilayer wiring layer 41 is provided over the pixel formation region 21a and the peripheral region 21b (the pixel array portion 2A and the peripheral portion 2B) of the semiconductor layer 21 in plan view.

Each wiring layer of the multilayer wiring layer 41 may include metal such as aluminum (Al) or copper (Cu), for example. The contact electrode may include metal such as tungsten (W) or Cu, for example. As the interlayer insulating film 43, a silicon oxide film or the like may be used, for example.

The transfer transistor of each pixel 3, the pixel transistors included in the pixel circuit 15, and the like are driven via the wiring of the multilayer wiring layer 41. Since the multilayer wiring layer 41 is arranged remote from the light incident surface (second surface S2) of the semiconductor layer 21, flexibility in wiring routing in the multilayer wiring layer 41 improves.

### Optical Layer

As illustrated in FIGS. 4 and 5, the optical layer 51 is provided adjacent to the light incident surface (second surface S2) of the semiconductor layer 21. Then, the optical layer 51 is provided over the pixel formation region 21a and the peripheral region 21b (the pixel array portion 2A and the peripheral portion 2B) of the semiconductor layer 21 in plan view.

The optical layer 51 includes, but is not limited to, a planarization layer 53, an optical filter layer 54, a lens layer 55, a protective layer 56, and the like stacked in this order from the second surface S2 of the semiconductor layer 21, for example.

The planarization layer 53 includes a light transmitting silicon oxide film, for example. Then, the planarization layer 53 covers all of the side, adjacent to the second surface S2 (light incident surface), of the semiconductor layer 21 so as to make the side, adjacent to the second surface S2, of the semiconductor layer 21 flat without unevenness.

The optical filter layer 54 is a black filter film, and is arranged at a position that coincides with the peripheral region 21b of the semiconductor layer 21 in plan view.

In the lens layer 55, a microlens 55a that condenses irradiation light and allows the condensed light to efficiently enter the photoelectric conversion region 22 is provided for each pixel 103.

The protective layer 56 includes a light transmitting silicon oxide film, for example. Then, the protective layer 56 is provided over the pixel formation region 21a and the peripheral region 21b (the pixel array portion 2A and the peripheral portion 2B) of the semiconductor layer 21 in plan view, and covers the microlens 55a of each pixel 3.

As illustrated in FIGS. 4 and 6, the optical layer 51 is provided with a bonding opening 57 that exposes the surface of the bonding pad 14. A connection member such as a bonding wire or a bump electrode is electrically and mechanically connected through the bonding opening 57.

### Relay Wiring

As illustrated in FIG. 6, the relay wiring 35 is provided in the peripheral region 21b of the semiconductor layer 21, extends in the thickness direction of the semiconductor layer 21, and is formed in the same layer as the first conductor 34 (see FIG. 5). The relay wiring 35 corresponds to a specific example of the “second conductor” of the present technology. Here, “the relay wiring 35 is formed in the same layer as the first conductor 34” means “the relay wiring 35 is formed in the same process and with the same material as the first conductor 34”.

The relay wiring 35 is provided in a dug portion 32b of the semiconductor layer 21 with the insulating film 33, provided along an inner wall (side wall and bottom wall) of the dug portion 32b, interposed between the relay wiring 35 and the inner wall. Then, the relay wiring 35 is provided to coincide with the bonding pad 14 in plan view, and relays (mediates) electrical connection between the bonding pad 14 and a wiring 44 of the multilayer wiring layer 41.

The dug portion 32b provided with the relay wiring 35 is formed in the same process as the dug portion 32a provided with the first conductor 34, in other words, in the same process as the dug portion 32a of the isolation region 31. That is, the first embodiment has, but not limited to, a configuration where the dug portion 32b extends through the semiconductor layer 21 from the first surface S1 to the second surface S2 in a manner similar to the dug portion 32a of the isolation region 31, and the relay wiring 35 is provided in the dug portion 32b extending through the semiconductor layer 21.

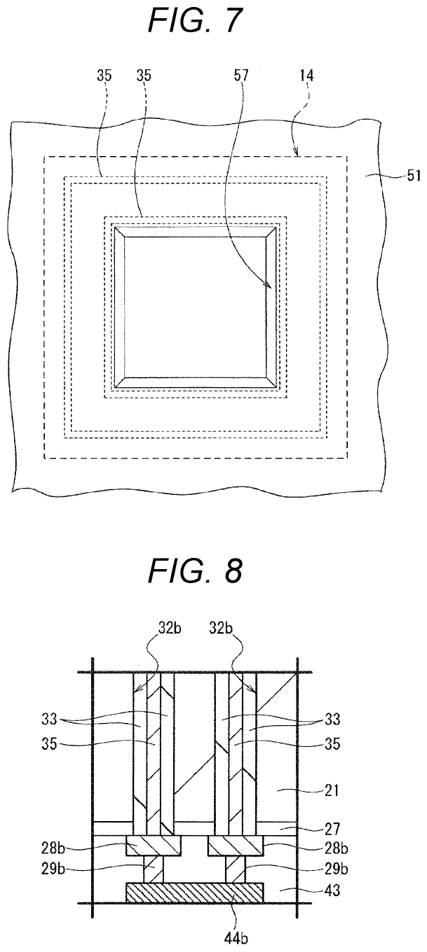

The relay wiring 35 is arranged adjacent to a peripheral edge (periphery) of the bonding pad 14 in plan view. In the first embodiment, as illustrated in FIGS. 6 and 7, the relay wiring 35 extends along the peripheral edge of the bonding pad 14 in plan view to form an annular planar pattern (ring planar pattern) along the peripheral edge of the bonding pad 14. Then, the relay wiring 35 is provided in a double layer in plan view. In the first embodiment, a width of the relay wiring 35 (width in a direction intersecting the thickness direction of the semiconductor layer 21) is designed to be identical to, for example, a width of the isolation region 31 (width in the same direction as the relay wiring 35).

As illustrated in FIGS. 6 and 8, in the thickness direction (Z direction) of the semiconductor layer 21, one end side of the relay wiring 35 is formed integrally with, but not limited to, the bonding pad 14, for example. Then, the other end side of the relay wiring 35 is electrically connected to an electrode pad 28b provided adjacent to the first surface S1 of the semiconductor layer 21 with an insulating film 27 interposed between the electrode pad 28b and the first surface S1. Then, the electrode pad 28b is electrically connected to a wiring 44b of the multilayer wiring layer 41 via a contact electrode 29b provided in the interlayer insulating film 43 of the multilayer wiring layer 41. That is, the bonding pad 14 is electrically connected to the wiring 44b of the multilayer wiring layer 41 via the relay wiring 35, the electrode pad 28b, and the contact electrode 29b. Then, the relay wiring 35 relays (mediates), in conjunction with the electrode pad 28b and the contact electrode 29b, the electrical connection between the bonding pad 14 and the wiring 44b of the multilayer wiring layer 41. The electrode pad 28b is covered with the interlayer insulating film 43 of the multilayer wiring layer 41 and includes, for example, a polycrystalline silicon film doped to reduce resistance.

Note that, in order to connect the bonding wire to the bonding pad 14, a ball bonding technique using ultrasonic vibration in combination with thermocompression bonding is used, for example. In this case, the impact generated by the compression bonding is transmitted to the dug portion 32b of the semiconductor layer 21 via the bonding pad 14, so that the relay wiring 35 is preferably arranged outside the contour of the bonding opening 57 in plan view.

### Back Wiring

As illustrated in FIG. 9, the back wiring 36 is provided in the peripheral region 21b of the semiconductor layer 21, extends in the thickness direction of the semiconductor layer 21, and is formed in the same layer as the first conductor 34. The back wiring 36 corresponds to a specific example of the “second conductor” of the present technology. Here, “the back wiring 36 is formed in the same layer as the first conductor 34” means “the back wiring 36 is formed in the same process and with the same material as the first conductor 34”.

The back wiring 36 is provided in a dug portion 32c of the semiconductor layer 21 with the insulating film 33, provided along an inner wall (side wall and bottom wall) of the dug portion 32c, interposed between the back wiring 36 and the inner wall. The dug portion 32c provided with the back wiring 36 is formed in the same process as the dug portion 32a provided with the first conductor 34, in other words, in the same process as the dug portion 32a of the isolation region 31. That is, the first embodiment has, but not limited to, a configuration where the dug portion 32c extends through the semiconductor layer 21 from the first surface S1 to the second surface S2 in a manner similar to the dug portion 32a of the isolation region 31, and the back wiring 36 is provided in the dug portion 32c extending through the semiconductor layer 21.

As illustrated in FIG. 9, in the thickness direction (Z direction) of the semiconductor layer 21, the other end side opposite to one end side of the back wiring 36 is electrically connected to an electrode pad 28c provided adjacent to the first surface S1 of the semiconductor layer 21 with the insulating film 27 interposed between the electrode pad 28c and the first surface S1. Then, the electrode pad 28c is electrically connected to a power supply wiring 44c of the multilayer wiring layer 41 via a contact electrode 29c provided in the interlayer insulating film 43 of the multilayer wiring layer 41. That is, the back wiring 36 is electrically connected to the wiring 44b of the multilayer wiring layer 41 via the electrode pad 28c and the contact electrode 29c. Then, although not illustrated in detail, the back wiring 36 extends, in a manner similar to the power supply wiring 44c of the multilayer wiring layer 41, to coincide with the power supply wiring 44c, and is electrically connected to the power supply wiring 44c at a plurality of connection points. The back wiring 36 functions as a back wiring of the power supply wiring 44c and reduces the effective resistance of the power supply wiring 44c.

Note that, in FIG. 9, as an example, four back wirings 36 are illustrated corresponding to the number of power supply wirings 44c of the multilayer wiring layer 41, but the number of the back wirings 36 is not limited to the number illustrated in FIG. 9.

### Second Substrate Portion

As illustrated in FIG. 4, the second substrate portion 60 includes a semiconductor layer 61 having a first surface S3 and a second surface S4 located on opposite sides in the thickness direction (Z), and a multilayer wiring layer 71 provided adjacent to the first surface S3 of the semiconductor layer 61.

The semiconductor layer 61 of the second substrate portion 60 is provided with, for example, a plurality of MOSFETS as field effect transistors included in the logic circuit 13 described above. As the semiconductor layer 61, a Si substrate, a SiGe substrate, an InGaAs substrate, or the like may be used, in a manner similar to the semiconductor layer 21.

Here, in the first embodiment, the semiconductor layer 61 corresponds to a specific example of a “second semiconductor layer” of the present technology.

As illustrated in FIG. 4, the multilayer wiring layer 71 is provided adjacent to the first surface S1 of the semiconductor layer 21 that is remote from the light incident surface (second surface S2), and includes a plurality of wiring layers including wiring, the plurality of wiring layers being stacked with an interlayer insulating film 73 interposed between the wiring layers. Wirings of different wiring layers are electrically connected by a contact electrode (via plug). Then, the multilayer wiring layer 71 is provided over the pixel formation region 21a and the peripheral region 21b (the pixel array portion 2A and the peripheral portion 2B) of the semiconductor layer 21 in plan view.

Each wiring layer of the multilayer wiring layer 71 may include metal such as aluminum (Al) or copper (Cu), for example. The contact electrode may include metal such as tungsten (W) or Cu, for example. As the interlayer insulating film 73, a silicon oxide film or the like may be used, for example.

### Bonding Between First Substrate Portion and Second Substrate Portion

As illustrated in FIG. 4, a first bonding metal pad 45 is provided in a surface layer portion of the multilayer wiring layer 41 of the first substrate portion 20 remote from the semiconductor layer 21. The first bonding metal pad 45 is provided in the interlayer insulating film 43 of the uppermost layer of the multilayer wiring layer 41 with a bonding surface exposed.

A second bonding metal pad 75 is provided in a surface layer portion of the multilayer wiring layer 71 of the second substrate portion 60 remote from the semiconductor layer 61. The second bonding metal pad 75 is provided in the interlayer insulating film 73 of the uppermost layer of the multilayer wiring layer 71 with a bonding surface exposed.

The first bonding metal pad 45 of the first substrate portion 20 and the second bonding metal pad 75 of the second substrate portion 60 are electrically and mechanically connected by metal-to-metal bonding with their respective bonding surfaces facing each other. Then, the metal-to-metal bonding between the first bonding metal pad 45 and the second bonding metal pad 75 makes the wiring of the multilayer wiring layer 41 of the first substrate portion 20 and the wiring of the multilayer wiring layer 71 of the second substrate portion 60 electrically continuous. Then, the metal-to-metal bonding between the first bonding metal pad 45 and the second bonding metal pad 75 creates a stack of the first substrate portion 20 and the second substrate portion 60 with the first substrate portion 20 and the second substrate portion 60 facing each other in the thickness direction (Z direction).

### Effects of First Embodiment

Next, main effects of the first embodiment will be described.

As described above, the solid-state imaging device 1A according to the first embodiment of the present technology includes the relay wiring 35 and the back wiring 36 as the second conductor provided in the peripheral region 21b of the semiconductor layer 21, extending in the thickness direction (Z direction) of the semiconductor layer 21, and formed in the same layer as the first conductor 34 in the isolation region 31. That is, the solid-state imaging device 1A uses the peripheral region 21b of the semiconductor layer 21 as a formation region for the relay wiring 35 and the back wiring 36. Therefore, the solid-state imaging device 1A according to the first embodiment allows a reduction in area occupied by the pixel formation region 21a as compared with a case where the relay wiring 35 and the back wiring 36 are provided in the pixel formation region 21a of the semiconductor layer 21, which allows a reduction in size of the solid-state imaging device 1A.

Furthermore, since the relay wiring 35 and the back wiring 36 are formed in the same layer as the first conductor 34 of the isolation region 31, the relay wiring 35 and the back wiring 36 can be provided at low cost as compared with a case where the relay wiring 35 and the back wiring 36 are formed in a layer different from the layer in which the first conductor 34 of the isolation region 31 is formed. This makes it possible to reduce the size and cost of the solid-state imaging device 1A.

Furthermore, since the electrical connection between the bonding pad 14 arranged adjacent to the second surface S2 (light incident surface) of the semiconductor layer 21 and the wiring 44b of the multilayer wiring layer 41 arranged adjacent to the first surface S1 of the semiconductor layer 21 can be relayed by the relay wiring 35, the bonding pad 14 can be arranged on a side of the semiconductor layer 21 remote from the multilayer wiring layer 41 (adjacent to the light incident surface).

It is therefore possible to make the bonding opening 57 shallow as compared with a case where the bonding pad 14 is arranged adjacent to the first surface S1 of the semiconductor layer 21 together with the multilayer wiring layer 41, so that it is possible to decrease the difficulty in connecting the connection member such as a bonding wire or a bump electrode to the bonding pad 14 and improve the manufacturing yield of an electronic apparatus including the solid-state imaging device 1A.

Furthermore, since the bonding opening 57 can be made shallow, it is possible to reduce, as compared with a case where the bonding pad 14 is arranged adjacent to the first surface S1 of the semiconductor layer 21 together with the multilayer wiring layer 41, a fluorine-based deposition amount adhering to the surface of the bonding pad 14 during processing of the bonding opening 57, and it is therefore possible to prevent connection failure between the connection member (bonding wire, bump electrode) and the bonding pad 14 caused by corrosion of a connection surface (upper surface) of the bonding pad 14. It is therefore possible to further improve the manufacturing yield of the electronic apparatus including the solid-state imaging device 1A.

Furthermore, since the relay wiring 35 is arranged in the peripheral region of the connection surface of the bonding pad 14 in plan view, it is possible to suppress, as compared with a case where the relay wiring 35 is arranged to coincide with a center region of the bonding pad 14 in plan view, the transmission, to the dug portion 32b or the relay wiring 35, of the impact generated when the bonding wire is thermocompression-bonded to the bonding pad 14, and it is possible to prevent damage to the dug portion 32b or the relay wiring 35 caused by thermocompression bonding. It is therefore possible to provide the solid-state imaging device 1A with high reliability.

Furthermore, since the relay wiring 35 is formed in an annular planar pattern extending along the peripheral edge of the connection surface of the bonding pad 14 in plan view, it is possible to prevent conduction failure between the bonding pad 14 and the relay wiring 35 and reduce contact resistance. It is therefore possible to provide the solid-state imaging device 1A with higher reliability.

Furthermore, since the power supply wiring 44c of the multilayer wiring layer 41 is backed by the back wiring 36, it is possible to reduce the effective resistance of the source wiring 44c to enhance the power supply.

Note that, in the first embodiment described above, the case where the pixel transistors (AMP, SEL, RST, FDG) included in the pixel circuit 15 are provided in the semiconductor layer 21 has been described, but the present technology can also be applied to a case where the pixel transistors (AMP, SEL, RST, FDG) included in the pixel circuit 15 are provided in the semiconductor layer 61.

### Modification of First Embodiment

In the first embodiment described above, the case where the annular relay wiring 35 is provided in a double layer has been described, but the present technology is not limited to the double-layer relay wiring 35.

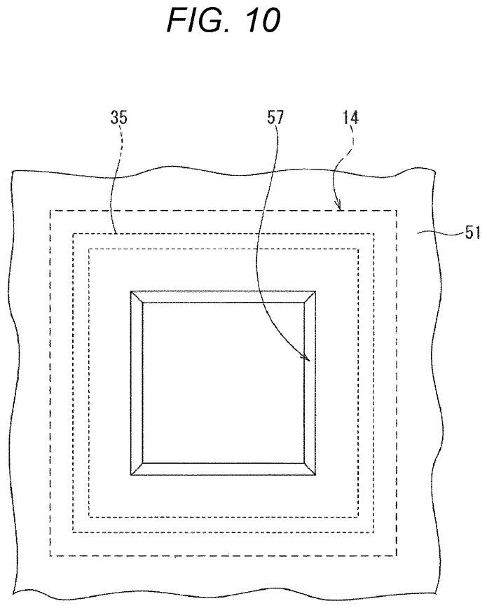

For example, as illustrated in FIG. 10, the relay wiring 35 may be a single-layer wiring or a triple-or more-layer wiring. Furthermore, the relay wiring 35 may be wider or narrower in width than the first conductor 34.

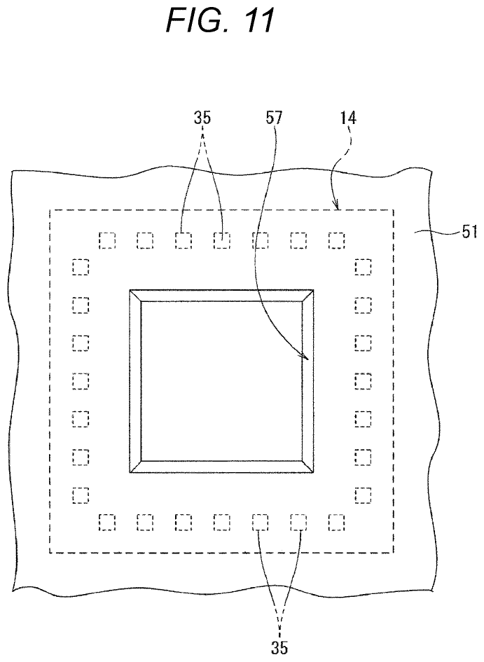

Furthermore, in the first embodiment described above, the case where the relay wiring 35 is formed in an annular planar pattern along the peripheral edge of the bonding pad 14 has been described, but, as illustrated in FIG. 11, a plurality of relay wirings 35 may be scattered along the peripheral edge of the bonding pad 14 in plan view. In this case, a transverse cross-sectional shape of each of the scattered relay wirings 35 (transverse cross-sectional shape along the direction intersecting the thickness direction of the first semiconductor layer) may be square or circular.

Furthermore, in the first embodiment described above, the case where the other end side of the relay wiring 35 and the wiring 44b of the multilayer wiring layer 41 are electrically connected via the electrode pad 28b and the contact electrode 29b has been described, but the present technology is not limited to such a connection form.

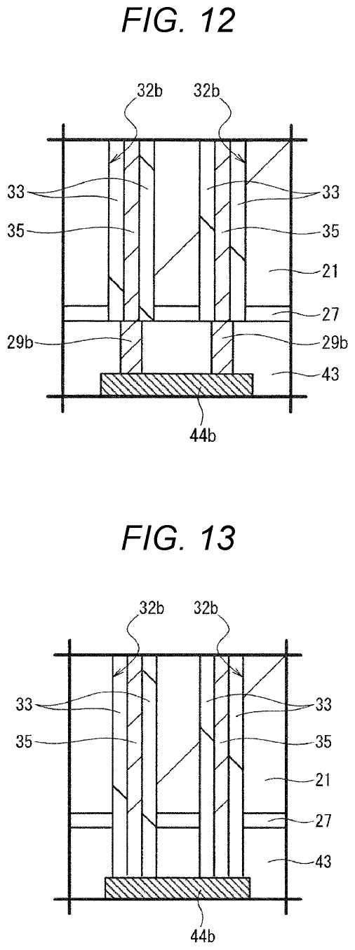

For example, a connection form where the electrode pad 28b illustrated in FIG. 8 is omitted, and as illustrated in FIG. 12, the other end side of the relay wiring 35 is directly connected to the contact electrode 29a, and the other end side of the relay wiring 35 and the wiring 44b of the multilayer wiring layer 41 are electrically connected via the contact electrode 29a may be employed.

Furthermore, a connection form where the electrode pad 28b and the contact electrode 29b illustrated in FIG. 8 are omitted, and as illustrated in FIG. 13, the other end side of the relay wiring 35 is directly connected to the wiring 44b of the multilayer wiring layer 41, and the other end side of the relay wiring 35 and the wiring 44b of the multilayer wiring layer 41 are electrically connected may be employed.

### Second Embodiment

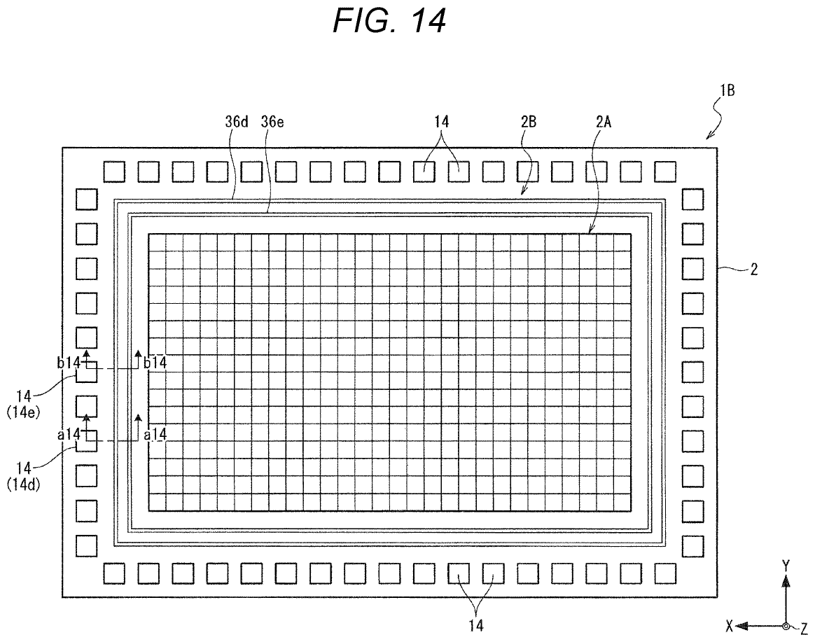

A solid-state imaging device 1B according to a second embodiment of the present technology is basically the same in configuration as the solid-state imaging device 1A according to the first embodiment described above, and differs from the first embodiment in that, as illustrated in FIGS. 14 to 16, the solid-state imaging device 1B includes back wirings 36d and 36e as the second conductor.

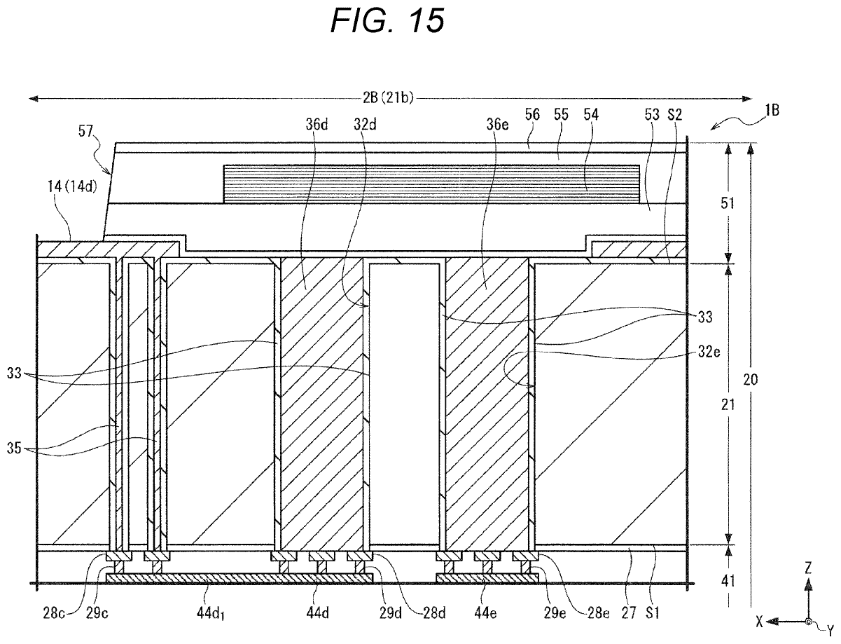

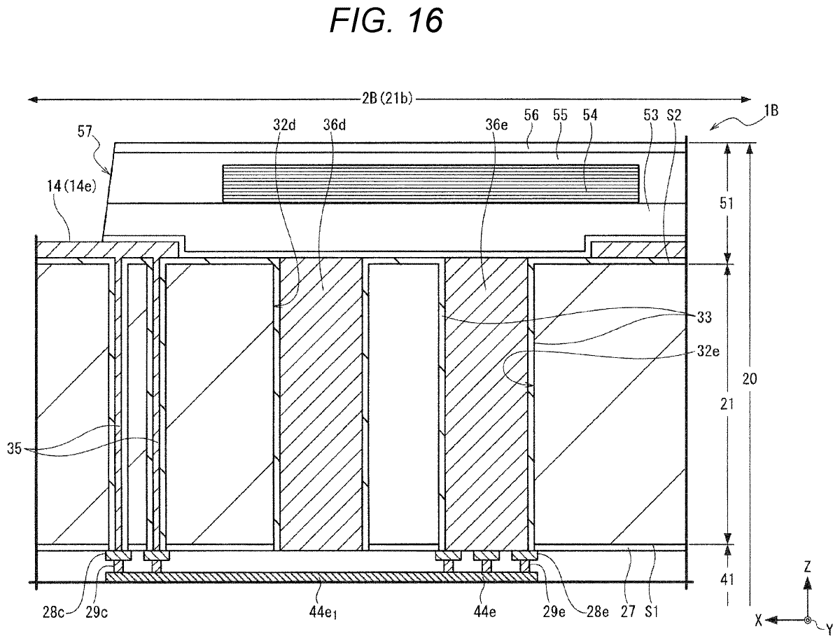

As illustrated in FIGS. 15 and 16, the back wirings 36d and 36e are provided in the peripheral region 21b of the semiconductor layer 21, extend in the thickness direction of the semiconductor layer 21, and are formed in the same layer as the first conductor 34. The back wirings 36d and 36e correspond to a specific example of the “second conductor” of the present technology. Here, “the back wirings 36d and 36e are formed in the same layer as the first conductor 34” means “the back wirings 36d and 36e are formed in the same process and with the same material as the first conductor 34”.

The solid-state imaging device 1B of the second embodiment uses the peripheral region 21b of the semiconductor layer 21 as a formation region for the back wirings 36d and 36e as the second conductor.

As illustrated in FIGS. 15 and 16, the back wiring 36d is provided in a dug portion 32d of the semiconductor layer 21 with the insulating film 33, provided along an inner wall (side wall) of the dug portion 32d, interposed between the back wiring 36d and the inner wall. The dug portion 32d provided with the back wiring 36d is formed in the same process as the dug portion 32a provided with the first conductor 34, in other words, in the same process as the dug portion 32a of the isolation region 31, in a manner similar to the dug portion 32c provided with the back wiring 36 of the first embodiment described above. That is, the second embodiment has, but not limited to, a configuration where the dug portion 32d extends through the semiconductor layer 21 from the first surface S1 to the second surface S2 in a manner similar to the dug portion 32a of the isolation region 31, and the back wiring 36d is provided in the dug portion 32d extending through the semiconductor layer 21.

As illustrated in FIGS. 15 and 16, the back wiring 36e is provided in a dug portion 32e of the semiconductor layer 21 with the insulating film 33, provided along an inner wall (side wall and bottom wall) of the dug portion 32e, interposed between the back wiring 36e and the inner wall. The dug portion 32e provided with the back wiring 36e is formed in the same process as the dug portion 32a provided with the first conductor 34, in other words, in the same process as the dug portion 32a of the isolation region 31, in a manner similar to the dug portion 32c provided with the back wiring 36 of the first embodiment described above. That is, the second embodiment has, but not limited to, a configuration where the dug portion 32e extends through the semiconductor layer 21 from the first surface S1 to the second surface S2 in a manner similar to the dug portion 32a of the isolation region 31, and the back wiring 36e is provided in the dug portion 32e extending through the semiconductor layer 21.

As illustrated in FIGS. 15 and 16, in the thickness direction (Z direction) of the semiconductor layer 21, the other end side opposite to one end side of the back wiring 36d is electrically connected to an electrode pad 28d provided adjacent to the first surface S1 of the semiconductor layer 21 with the insulating film 27 interposed between the electrode pad 28d and the first surface S1. Then, the electrode pad 28d is electrically connected to a power supply wiring 44d of the multilayer wiring layer 41 via a contact electrode 29d provided in the interlayer insulating film 43 of the multilayer wiring layer 41. That is, the back wiring 36d is electrically connected to the power supply wiring 44d of the multilayer wiring layer 41 via the electrode pad 28d and the contact electrode 29d.

As illustrated in FIGS. 14 and 15, the back wiring 36d is formed in an annular planar pattern extending around the pixel array portion 2A in plan view in the peripheral portion 2B of the semiconductor chip 2 (the peripheral region 21b of the semiconductor layer 21). Then, although not illustrated in detail, the power supply wiring 44d of the multilayer wiring layer 41 is also formed in an annular planar pattern extending around the pixel array portion 2A (the pixel formation region 21a of the semiconductor layer 21), in a manner similar to the back wiring 36d. Then, the back wiring 36d and the power supply wiring 44d extend to coincide with each other in plan view, and the back wiring 36d and the power supply wiring 44d are electrically connected at a plurality of connection points. The back wiring 36d functions as a back wiring of the power supply wiring 44d and reduces the effective resistance of the power supply wiring 44d.

As illustrated in FIG. 15, the power supply wiring 44d is formed integrally with a wiring 44d₁formed in the same layer as the power supply wiring 44d in the multilayer wiring layer 41. Then, the wiring 44d₁ is drawn out from the power supply wiring 44d to make one end side coincident with a bonding pad 14d among the plurality of bonding pads 14 in plan view. Then, the wiring 44d₁ has one end side electrically connected to the bonding pad 14d via a contact electrode 49c, the electrode pad 28c, and the relay wiring 35.

Although not limited thereto, the first reference potential of, for example, 0 V is applied to the bonding pad 14d as the power supply potential. Then, when the first reference potential of 0 V is applied to the bonding pad 14d, the power supply wiring 44d of the multilayer wiring layer 41 and the back wiring 36d are fixed to the first reference potential.

As illustrated in FIGS. 15 and 16, in the thickness direction (Z direction) of the semiconductor layer 21, the other end side opposite to one end side of the back wiring 36e is electrically connected to an electrode pad 28e provided adjacent to the first surface S1 of the semiconductor layer 21 with the insulating film 27 interposed between the electrode pad 28e and the first surface S1. Then, the electrode pad 28e is electrically connected to a power supply wiring 44e of the multilayer wiring layer 41 via a contact electrode 29e provided in the interlayer insulating film 43 of the multilayer wiring layer 41. That is, the back wiring 36e is electrically connected to the power supply wiring 44e of the multilayer wiring layer 41 via the electrode pad 28e and the contact electrode 29e.

As illustrated in FIGS. 14 and 16, the back wiring 36e is formed in an annular planar pattern extending around the pixel array portion 2A in plan view in the peripheral portion 2B of the semiconductor chip 2 (the peripheral region 21b of the semiconductor layer 21). Then, although not illustrated in detail, the power supply wiring 44e of the multilayer wiring layer 41 is also formed in an annular planar pattern extending around the pixel array portion 2A, in a manner similar to the back wiring 36e. Then, the back wiring 36e and the power supply wiring 44e extend to coincide with each other in plan view, and the back wiring 36e and the power supply wiring 44e are electrically connected at a plurality of connection points. The back wiring 36e functions as a back wiring of the power supply wiring 44e and reduces the effective resistance of the power supply wiring 44e. The back wiring 36e is arranged adjacent to the pixel array portion 2A (the pixel formation region 21a of the semiconductor layer 21) relative to the back wiring 36d.

As illustrated in FIG. 16, the power supply wiring 44e is formed integrally with a wiring 44e₁ formed in the same layer as the power supply wiring 44e in the multilayer wiring layer 41. Then, the wiring 44e₁ is drawn out from the power supply wiring 44e to make one end side coincident with a bonding pad 14e among the plurality of bonding pads 14 in plan view. Then, the wiring 44e₁ has the one end side electrically connected to the bonding pad 14e via a contact electrode 59c, the electrode pad 28c, and the relay wiring 35.

Although not limited thereto, for example, a second positive reference potential higher than the first reference potential is applied to the bonding pad 14e as the power supply potential. For example, 4.5 V is applied as the second positive reference potential. Then, when the second positive reference potential is applied to the bonding pad 14e, the power supply wiring 44e of the multilayer wiring layer 41 and the back wiring 36e are fixed to the second reference potential.

As illustrated in FIGS. 15 and 16, the power supply wiring 44d and the back wiring 36d are electrically insulated and isolated from the power supply wiring 44e and the back wiring 36e. The wiring 44e₁ is drawn out longer than the wiring 44d₁ and crosses a break in the power supply wiring 44d extending annularly.

Each of the back wirings 36d and 36e is larger in width than the back wiring 36 of the first embodiment described above.

The solid-state imaging device 1B according to the second embodiment can also produce effects similar to the effects produced by the solid-state imaging device 1A according to the first embodiment described above.

Furthermore, since the back wirings 36d and 36e of the second embodiment are each wider in width than the back wiring 36 of the first embodiment described above, it is possible to further reduce the effective resistance of each of the power supply wirings 44d and 44e of the multilayer wiring layer 41 and further enhance the power supply.

Furthermore, since the back wirings 36d and 36e of the second embodiment are each formed in an annular planar pattern extending around the pixel array portion 2A in plan view in the peripheral portion 2B of the semiconductor chip 2 (the peripheral region 21b of the semiconductor layer 21), the back wirings 36d and 36e can function as guard rings.

### Third Embodiment

A solid-state imaging device 1C according to a third embodiment of the present technology is basically the same in configuration as the solid-state imaging device 1A according to the first embodiment described above, and is different from the first embodiment in that the solid-state imaging device 1C includes a capacitor element Ce having a second electrode 39 as the second conductor.

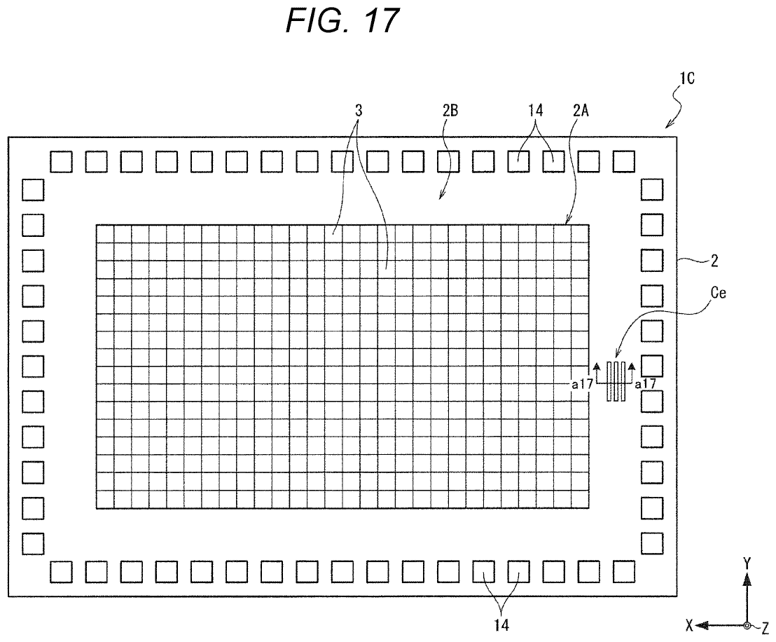

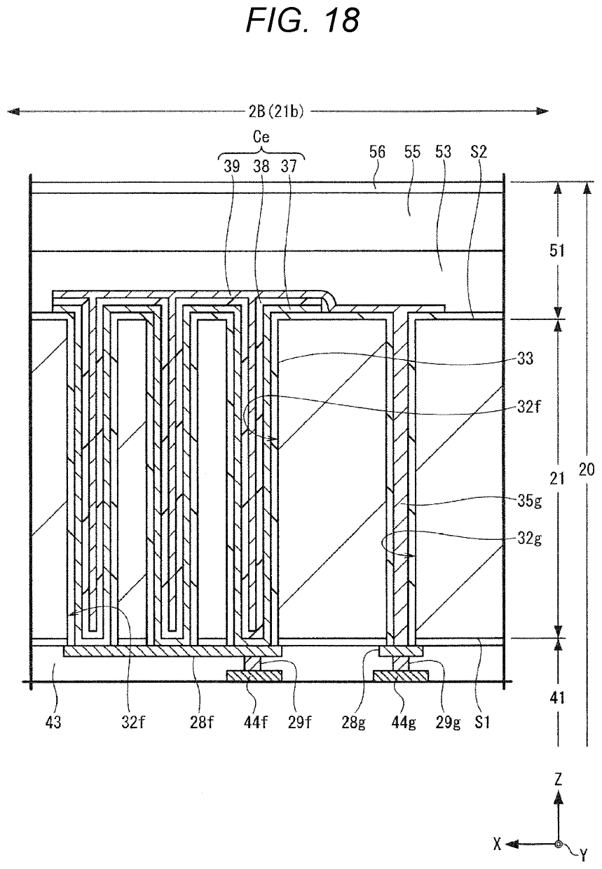

As illustrated in FIGS. 17 and 18, the capacitor element Ce is provided in the peripheral region 21b of the semiconductor layer 21 (the peripheral portion 2B of the semiconductor chip 2). The capacitor element Ce includes a first electrode 37 provided in a dug portion 32f of the semiconductor layer 21 with the insulating film 33, provided along an inner wall (side wall) of the dug portion 32f, interposed between the first electrode 37 and the inner wall, a dielectric film 38 provided along the inner wall of the dug portion 32f with the first electrode 37 interposed between the dielectric film 38 and the insulating film 33, and the second electrode 39 provided in the dug portion 32f with the dielectric film 38 interposed between the second electrode 39 and the first electrode 37. That is, the capacitor element Ce has a stack structure in which the dielectric film 38 is sandwiched between the first electrode 37 and the second electrode 39 from a film thickness direction of the dielectric film 38 in the dug portion 32f of the semiconductor layer 21.

The second electrode 39 is provided in the peripheral region 21b of the semiconductor layer 21, extends in the thickness direction of the semiconductor layer 21, and is formed in the same layer as the first conductor 34, in a manner similar to the relay wiring 35 and the back wiring 36 of the first embodiment described above. The second electrode 39 corresponds to a specific example of the “second conductor” of the present technology. Here, “the second electrode 39 is formed in the same layer as the first conductor 34” means “the second electrode 39 is formed in the same process and with the same material as the first conductor 34”.

In the solid-state imaging device 1C of the third embodiment, the peripheral region 21b of the semiconductor layer 21 is used as a formation region for the capacitor element Ce including the second electrode 39 as the second conductor.

The dug portion 32f provided with the second electrode 39 is formed in the same process as the dug portion 32a provided with the first conductor 34, in other words, in the same process as the dug portion 32a of the isolation region 31, in a manner similar to the dug portion 32c provided with the back wiring 36 of the first embodiment described above. That is, the third embodiment has, but not limited to, a configuration where the dug portion 32f extends through the semiconductor layer 21 from the first surface S1 to the second surface S2 in a manner similar to the dug portion 32a of the isolation region 31, and the second electrode 39 is provided in the dug portion 32f extending through the semiconductor layer 21.

Note that, in FIG. 18, three dug portions 32f arranged in parallel are illustrated as an example, but the number of the dug portions 32f is not limited to the number illustrated in FIG. 18.

As illustrated in FIG. 18, the first electrode 37 is electrically connected, on a side adjacent to the first surface S1, of the semiconductor layer 21, to an electrode pad 28f provided in the interlayer insulating film 43 of the multilayer wiring layer 41. Then, the electrode pad 28f is electrically connected to a wiring 44f of the multilayer wiring layer 41 via a contact electrode 29f provided in the interlayer insulating film 43 of the multilayer wiring layer 41. That is, the first electrode 37 is electrically connected to the wiring 44f of the multilayer wiring layer 41 via the electrode pad 28f and the contact electrode 29f.

As illustrated in FIG. 18, the second electrode 39 is formed integrally with a relay wiring 35g on a side, adjacent to the second surface S2, of the semiconductor layer 21. The relay wiring 35g is provided in the peripheral region 21b of the semiconductor layer 21, extends in the thickness direction of the semiconductor layer 21, and is formed in the same layer as the first conductor 34 (see FIG. 35), in a manner similar to the relay wiring 35 and the back wiring 36 of the first embodiment described above. The relay wiring 35g corresponds to a specific example of the “second conductor” of the present technology. Here, “the relay wiring 35g is formed in the same layer as the first conductor 34” means “the relay wiring 35g is formed in the same process and with the same material as the first conductor 34”.

The relay wiring 35g is provided in a dug portion 32g of the semiconductor layer 21 with the insulating film 33, provided along an inner wall (side wall and bottom wall) of the dug portion 32c, interposed between the relay wiring 35g and the inner wall. The dug portion 32g provided with the relay wiring 35g is formed in the same process as the dug portion 32a provided with the first conductor 34, in other words, in the same process as the dug portion 32a of the isolation region 31. That is, the third embodiment has, but not limited to, a configuration where the dug portion 32f extends through the semiconductor layer 21 from the first surface S1 to the second surface S2 in a manner similar to the dug portion 32a of the isolation region 31, and the relay wiring 35g is provided in the dug portion 32f extending through the semiconductor layer 21.

In the thickness direction (Z direction) of the semiconductor layer 21, the other end side opposite to one end side of the relay wiring 35g is electrically connected to an electrode pad 28g provided adjacent to the first surface S1 of the semiconductor layer 21 with the insulating film 27 interposed between the electrode pad 28g and the first surface S1. Then, the electrode pad 28g is electrically connected to a wiring 44g of the multilayer wiring layer 41 via a contact electrode 29g provided in the interlayer insulating film 43 of the multilayer wiring layer 41. That is, the relay wiring 35g is electrically connected to the wiring 44g of the multilayer wiring layer 41 via the electrode pad 28g and the contact electrode 29g.

As the first electrode 37, for example, a titanium nitride (TiN) film may be used. As the dielectric film 38, for example, a ZrO/AlO/Zro film, a HfO/AlO/HfO film, or the like that is high in relative permittivity may be used.

The solid-state imaging device 1C according to the third embodiment can also produce effects similar to the effects produced by the solid-state imaging device 1A according to the first embodiment described above.

Furthermore, the capacity of the capacitor element Ce of the third embodiment can be increased in accordance with the thickness direction of the semiconductor layer 21 and the number of dug portions 32f, and the capacitor element Ce having a large capacity can be easily formed. Furthermore, since the capacitor element Ce is provided in the peripheral region 21b of the semiconductor layer 21, it is possible to mount the capacitor element Ce having a large capacity while suppressing an increase in size of the solid-state imaging device 1C.

Note that, in the third embodiment described above, the case where the second electrode 39 of the capacitor element Ce includes the second conductor has been described, but the first electrode 37 of the capacitor element Ce may include the second conductor. In this case, the first electrode 37 of the capacitor element Ce is formed in the same layer as the first conductor 34 of the isolation region 31.

### Fourth Embodiment

### Application Example to Electronic Apparatus

The present technology (technology of the present disclosure) can be applied to various electronic apparatuses such as an imaging device such as a digital still camera or a digital video camera, a mobile phone having an imaging function, or other devices having an imaging function, for example.

FIG. 19 is a diagram illustrating a schematic configuration of an electronic apparatus (for example, a camera) according to a fourth embodiment of the present technology.

As illustrated in FIG. 19, an electronic apparatus 100 includes the solid-state imaging device 101, the optical lens 102, a shutter device 103, a drive circuit 104, and a signal processing circuit 105. The electronic apparatus 100 indicates an embodiment in a case where the solid-state imaging devices 1A, 1B, and 1C according to the first to third embodiments of the present technology are each used as the solid-state imaging device 101 in an electronic apparatus (for example, a camera).

The optical lens 102 forms an image of image light (incident light 106) from a subject on the imaging surface of the solid-state imaging device 101. As a result, signal charges are accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with a drive signal (a timing signal) supplied from the drive circuit 104, the solid-state imaging device 101 performs signal transfer. The signal processing circuit 105 performs various kinds of signal processing on a signal (pixel signal (image signal)) output from the solid-state imaging device 101. A video signal subjected to the signal processing is stored into a storage medium such as a memory, or is output to a monitor.

Such a configuration reduces the size of the solid-state imaging device 101, so that the electronic apparatus 100 of the fourth embodiment can be reduced in size.

Note that the electronic apparatus 100 to which the solid-state imaging device of each of the embodiments described above can be applied is not limited to a camera, and the solid-state imaging device can also be applied to other electronic apparatuses. For example, the solid-state imaging device may be applied to an imaging device such as a camera module for a mobile device such as a mobile phone or a tablet terminal.

Furthermore, the present technology can be applied to any photodetection device including not only the above-described solid-state imaging device as an image sensor but also a ranging sensor that is also called a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. This ranging sensor may also employ the structure of the solid-state imaging device described above.

Note that the present technology may also have the following configurations.
(1)

A photodetection device including:
a semiconductor layer including a pixel formation region and a peripheral region arranged outside the pixel formation region;
an isolation region provided in the pixel formation region of the semiconductor layer and including a first conductor extending in a thickness direction of the semiconductor layer; and
a second conductor provided in the peripheral region of the semiconductor layer, extending in the thickness direction of the semiconductor layer, and formed in the same layer as the first conductor.
(2)

The photodetection device according to the above (1), in which the first conductor and the second conductor are each provided in a corresponding dug portion extending through the semiconductor layer.
(3)

The photodetection device according to the above (1) or (2), further including:
a multilayer wiring layer provided over the pixel formation region and the peripheral region of the semiconductor layer on a side of the semiconductor layer remote from a light incident surface; and
a bonding pad provided on a side of the peripheral region of the semiconductor layer adjacent to the light incident surface, in which
the second conductor functions as a relay wiring that is provided to coincide with the bonding pad in plan view and electrically connects the bonding pad and a wiring of the multilayer wiring layer.
(4)

The photoelectric conversion device according to any one of the above (1) to (3), in which the relay wiring is arranged adjacent to a peripheral edge of the bonding pad in plan view.
(5)

The photoelectric conversion device according to any one of the above (1) to (4), in which the relay wiring is formed in an annular planar pattern along a peripheral edge of the bonding pad in plan view.
(6)

The photoelectric conversion device according to any one of the above (1) to (4), in which a plurality of the relay wirings is scattered along a peripheral edge of the bonding pad in plan view.
(7)

The photoelectric conversion device according to the above (1), further including
a multilayer wiring layer provided on a side of the semiconductor layer remote from a light incident surface to coincide with the pixel formation region and the peripheral region of the semiconductor layer in plan view, in which
the multilayer wiring layer includes a power supply wiring, and
the second conductor functions as a back wiring electrically connected to the power supply wiring.
(8)

The photoelectric conversion device according to the above (7), in which the back wiring is formed in an annular planar pattern around the pixel formation region of the semiconductor layer in plan view.
(9)

The photodetection device according to the above (1) or (2), further including
a capacitor element provided in the peripheral region of the semiconductor layer, in which
the capacitor element includes a first electrode, a dielectric film, and a second electrode, and
the second conductor functions as one of the first electrode or the second electrode.
(10)

The photodetection device according to the above (3) or (7), further including:
a second semiconductor layer provided on a side of the multilayer wiring layer remote from the semiconductor layer defined as a first semiconductor layer to coincide with the first semiconductor layer;
a photoelectric conversion element provided in the first semiconductor layer; and
a pixel circuit that includes a pixel transistor provided in the first semiconductor layer or the second semiconductor layer and converts, into a pixel signal, a signal charge generated by photoelectric conversion in the photoelectric conversion element.
(11)

An electronic apparatus including:
a photodetection device;
an optical lens that forms an image of image light from a subject on an imaging surface of the photodetection device; and
a signal processing circuit that performs signal processing on a signal output from the photodetection device, in which
the photodetection device includes:
a semiconductor layer including a pixel formation region and a peripheral region arranged outside the pixel formation region;
an isolation region provided in the pixel formation region of the semiconductor layer and including a first conductor extending in a thickness direction of the semiconductor layer; and
a second conductor provided in the peripheral region of the semiconductor layer, extending in the thickness direction of the semiconductor layer, and formed in the same layer as the first conductor.

The scope of the present technology is not limited to the exemplary embodiments illustrated in the drawings and described above, but includes all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A Solid-state imaging device
2A Pixel array portion
2B Peripheral portion
3 Pixel
4 Vertical drive circuit
8 Column signal processing circuit
6 Horizontal drive circuit
7 Output circuit
8 Control circuit
10 Pixel drive line
11 Vertical signal line
13 Logic circuit
14 Bonding pad
15 Pixel circuit
20 First substrate portion
21 Semiconductor layer (first semiconductor layer)
21a Pixel formation region
21b Peripheral region
22 Photoelectric conversion region
23 p-type well region
24 n-type semiconductor region
25 Photoelectric conversion portion
26 Gate electrode
27 Insulating film
28b, 28c, 28d, 28e Electrode pad
29b, 29c, 29d, 29e Contact electrode
31 Isolation region
32a, 32b, 32c Dug portion
33 Insulating film
34 First conductor
35 Relay wiring (second conductor)
36, 36d, 36e Back wiring (second conductor)
37 First electrode
38 Dielectric film
39 Second electrode (second conductor)
41 Multilayer wiring layer
43 Interlayer insulating film
44b, 44c, 44d, 44d₁, 44e, 44e₁ Wiring
45 First bonding metal pad
51 Optical layer
53 Planarization layer
54 Optical filter layer
55 Lens layer
56 Protective layer
57 Bonding opening
60 Second substrate portion
61 Semiconductor layer (second semiconductor layer)
71 Multilayer wiring layer
73 Interlayer insulating film
75 Second bonding metal pad
AMP Amplification transistor
Ce Capacitor element
FD Charge holding region
FDG Switching transistor
PD Photoelectric conversion element
RST Reset transistor
SEL Selection transistor
TR Transfer transistor
Vdd Power supply line

1. A photodetection device comprising:
a semiconductor layer including a pixel formation region and a peripheral region arranged outside the pixel formation region;
an isolation region provided in the pixel formation region of the semiconductor layer and including a first conductor extending in a thickness direction of the semiconductor layer; and
a second conductor provided in the peripheral region of the semiconductor layer, extending in the thickness direction of the semiconductor layer, and formed in a same layer as the first conductor.

2. The photodetection device according to claim 1, wherein the first conductor and the second conductor are each provided in a corresponding dug portion extending through the semiconductor layer.

3. The photodetection device according to claim 1, further comprising:
a multilayer wiring layer provided over the pixel formation region and the peripheral region of the semiconductor layer on a side of the semiconductor layer remote from a light incident surface; and
a bonding pad provided on a side of the peripheral region of the semiconductor layer adjacent to the light incident surface, wherein
the second conductor functions as a relay wiring that is provided to coincide with the bonding pad in plan view and electrically connects the bonding pad and a wiring of the multilayer wiring layer.

4. The photoelectric conversion device according to claim 3, wherein the relay wiring is arranged adjacent to a peripheral edge of the bonding pad in plan view.

5. The photoelectric conversion device according to claim 3, wherein the relay wiring is formed in an annular planar pattern along a peripheral edge of the bonding pad in plan view.

6. The photoelectric conversion device according to claim 3, wherein a plurality of the relay wirings is scattered along a peripheral edge of the bonding pad in plan view.

7. The photoelectric conversion device according to claim 1, further comprising
a multilayer wiring layer provided on a side of the semiconductor layer remote from a light incident surface to coincide with the pixel formation region and the peripheral region of the semiconductor layer in plan view, wherein
the multilayer wiring layer includes a power supply wiring, and
the second conductor functions as a back wiring electrically connected to the power supply wiring.

8. The photoelectric conversion device according to claim 7, wherein the back wiring is formed in an annular planar pattern around the pixel formation region of the semiconductor layer in plan view.

9. The photodetection device according to claim 1, further comprising
a capacitor element provided in the peripheral region of the semiconductor layer, wherein
the capacitor element includes a first electrode, a dielectric film, and a second electrode, and
the second conductor functions as one of the first electrode or the second electrode.

10. The photodetection device according to claim 3, further comprising:
a second semiconductor layer provided on a side of the multilayer wiring layer remote from the semiconductor layer defined as a first semiconductor layer to coincide with the first semiconductor layer;
a photoelectric conversion element provided in the first semiconductor layer; and
a pixel circuit that includes a pixel transistor provided in the first semiconductor layer or the second semiconductor layer and converts, into a pixel signal, a signal charge generated by photoelectric conversion in the photoelectric conversion element.

11. An electronic apparatus comprising:
a photodetection device;
an optical lens that forms an image of image light from a subject on an imaging surface of the photodetection device; and
a signal processing circuit that performs signal processing on a signal output from the photodetection device, wherein
the photodetection device includes:
a semiconductor layer including a pixel formation region and a peripheral region arranged outside the pixel formation region;
an isolation region provided in the pixel formation region of the semiconductor layer and including a first conductor extending in a thickness direction of the semiconductor layer; and
a second conductor provided in the peripheral region of the semiconductor layer, extending in the thickness direction of the semiconductor layer, and formed in a same layer as the first conductor.
